(19) United States
(12) Patent Application Publication
(10) Pub. No.: US 2010/0187602 A1
(43) Pub. Date: Jul. 29, 2010

(54) METHODS FOR MAKING SEMICONDUCTOR DEVICES USING NITRIDE CONSUMPTION LOCOS OXIDATION

(76) Inventors: Debra S. Woolsey, Salt Lake City, UT (US); Tony L. Olsen, Salt Lake City, UT (US); Gordon K. Madson, Salt Lake City, UT (US)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/362,321

(22) Filed: Jan. 29, 2009

(51) Int. Cl. H01L 29/78; H01L 21/336

(52) U.S. Cl. 257/330; 438/589; 257/E21.41; 257/E29.262

(57) ABSTRACT

Semiconductor devices and methods for making such devices using nitride consumption LOCOS oxidation are described. The semiconductor devices contain a planar field oxide structure that has been grown using a nitride layer as an oxidation mask. Once the field oxide structure has been grown, the nitride mask is not etched away, but rather converted to an oxide layer by an oxidation process using radicals of hydrogen and oxygen. The semiconductor devices also contain a shielded gate trench MOSFET that can be created using an oxide layer with an overlying nitride layer as the channel (sidewall) gate dielectric. An inter-poly-dielectric (IPD) layer can be formed from a thermally grown oxide which uses the nitride layer as a oxidation mask. The thickness of the IPD layer can be adjusted to any thickness needed with minimal effect of the channel gate dielectric layer. An oxidation process using radicals of hydrogen and oxygen can be preformed to consume the nitride layer and form the gate oxide in the channel region. Since the gate channel nitride acts as a barrier to the oxidation, the IPD oxide layer can be grown to any needed thickness with minimal oxidation to the channel gate and the nitride layer can be removed without any etching processes. Other embodiments are described.

### FIELD

This application relates generally to semiconductor devices and methods for making such devices. More specifically, this application describes semiconductor devices and methods for making such devices using nitride consumption LOCOS oxidation.

### BACKGROUND

In integrated circuit (IC) fabrication, semiconductor devices such as transistors may be formed on a semiconductor wafer or substrate, which is typically made of silicon. One type of device, a metal oxide silicon field effect transistor (MOSFET) device, can be widely used in numerous applications, including automotive electronics, disk drives and power supplies. Generally, these devices function as switches, and they are used to connect a power supply to a load. The resistance of the MOSFET device should be as low as possible when the switch is closed. Otherwise, power is wasted and excessive heat may be generated.

One type of MOSFET, a trench MOSFET, is illustrated in FIG. 1. Gates 102 and 104 are formed in trenches and surrounded by gate oxide layers 106 and 108, respectively. The MOSFET device 100 can be formed in an N-epitaxial layer 110. A N+ source region 112 is formed at the surface of epitaxial layer 110. A P+ contact region 114 is also formed at the surface of epitaxial layer 110. A P-body region 116 is located below N+ source region 112 and P+ contact region 114. A metal source contact 118 contacts the source region 112 and shorts the source region 112 to the P+ contact region 114 and P body region 116.

The N-epitaxial layer 110 is formed on a substrate 120, and a drain contact (not shown) is located at the bottom of the substrate 120. The contact for the gates 102 and 104 is likewise not shown, but it is generally made by extending the conductive gate material outside of the trench and forming a metal contact at a location remote from the individual cells. The gate is typically made of phosphorus or boron doped polysilicon.

A region 111 of N-epitaxial layer 110 between the substrate 120 and the P body 116 is generally more lightly doped with N-type impurities than substrate 120. This increases the ability of MOSFET 100 to withstand high voltages. Region 111 is sometimes referred to as a “lightly doped” or “drift” region (“drift” referring to the movement of carriers in an electric field). Drift region 111 and substrate 120 constitute the drain of MOSFET 100.

One feature making the trench configuration attractive is that the current flows vertically through the channel of the MOSFET. This permits a higher cell density than other MOSFETs where the current flows horizontally through the channel and then vertically through the drain. Greater cell density generally means more MOSFETs can be manufactured per unit area of the substrate, thereby increasing the yield of the semiconductor device contains the trench MOSFET.

### SUMMARY

This application relates to semiconductor devices and methods for making such devices using nitride consumption LOCOS oxidation. The semiconductor devices contain a planar field oxide structure that has been grown using a nitride layer as an oxidation mask. Once the field oxide structure has been grown, the nitride mask is not etched away, but rather converted to an oxide layer by an oxidation process using radicals of hydrogen and oxygen. The semiconductor devices also contain a shielded gate trench MOSFET that can be created using an oxide layer with an overlying nitride layer as the channel (sidewall) gate dielectric. An inter-poly-dielectric (IPD) layer can be formed from a thermally grown oxide which uses the nitride layer as a oxidation mask. The thickness of the IPD layer can be adjusted to any thickness needed with minimal effect of the channel gate dielectric layer. An oxidation process using radicals of hydrogen and oxygen can be preformed to consume the nitride layer and form the gate oxide in the channel region. Since the gate channel nitride acts as a barrier to the oxidation, the IPD oxide layer can be grown to any needed thickness with minimal oxidation to the channel gate and the nitride layer can be removed without any etching processes.

### BRIEF DESCRIPTION OF THE DRAWINGS

The following description can be better understood in light of the Figures, in which:

FIG. 1 shows a prior art trench MOSFET device;

FIG. 2 depicts some embodiments of a method for making semiconductor devices where an oxidation mask has been formed over a nitride film;

FIG. 3 shows some embodiments of a method for making semiconductor devices where a part of a nitride layer has been converted to an oxide layer;

FIG. 4 depicts some embodiments of a method for making semiconductor devices where part of a nitride mask has been formed over an oxide film;

FIGS. 5-6 shows some embodiments of a method for making semiconductor devices containing a field oxide structure using a LOCOS process;

FIGS. 7A and 8A show SEM photographs for those embodiments of semiconductor devices where a nitride layer has been removed by etching;

FIGS. 7B and 8B show SEM photographs for those embodiments of semiconductor devices where a nitride layer has been converted to an oxide layer;

FIGS. 9A, 9B, and 10A-10G depicts some embodiments of a method for making semiconductor devices containing a dual-gate MOSFET device; and

FIGS. 11-14 depicts some embodiments of a method for making semiconductor devices containing a shielded dual-gate MOSFET device.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor devices and associated methods of making and using the devices can be implemented and used without employing these specific details. Indeed, the semiconductor devices and associated methods can be placed into practice by modifying the illustrated devices and methods and can be used in conjunction with any other apparatus and techniques conventionally used in the industry. For example, while the invention is described with reference to MOSFET devices, it could be modified for other devices formed in trenches which need to be isolated, such as bipolar devices, BDCMOS devices, or other types of transistor structures. As well, although the devices of the invention are described with reference to a particular type of conductivity (P or N), the devices can be configured with the opposite type of conductivity (N or P, respectively) by appropriate modifications.

Some embodiments of the semiconductor devices and methods for making such device are shown in FIG. 2. In these embodiments, the methods for making the semiconductor packages contain a process for consuming a nitride layer using a radical oxidation process to thereby form an oxide layer. In these embodiments, a nitride layer 15 can be formed on an oxide layer 10. The oxide layer 10 can be any oxide layer known in the art, including a chemical vapor deposition (CVD) oxide or an oxide layer that is formed by oxidizing an underlying Si substrate (not shown). The oxide layer 10 can have any thickness for the desired semiconductor device in which it will be used, including a thickness ranging from about 50 to about 1000 Å.

The nitride layer 15 can be formed using any process known in the art. In some instances, the nitride layer 15 can be a CVD nitride layer or a nitride layer that is formed by nitriding the underlying oxide layer using any process known in the art. The nitride layer 15 can have any thickness that is needed for blocking oxidation, including a thickness ranging from about 100 to about 1000 Å.

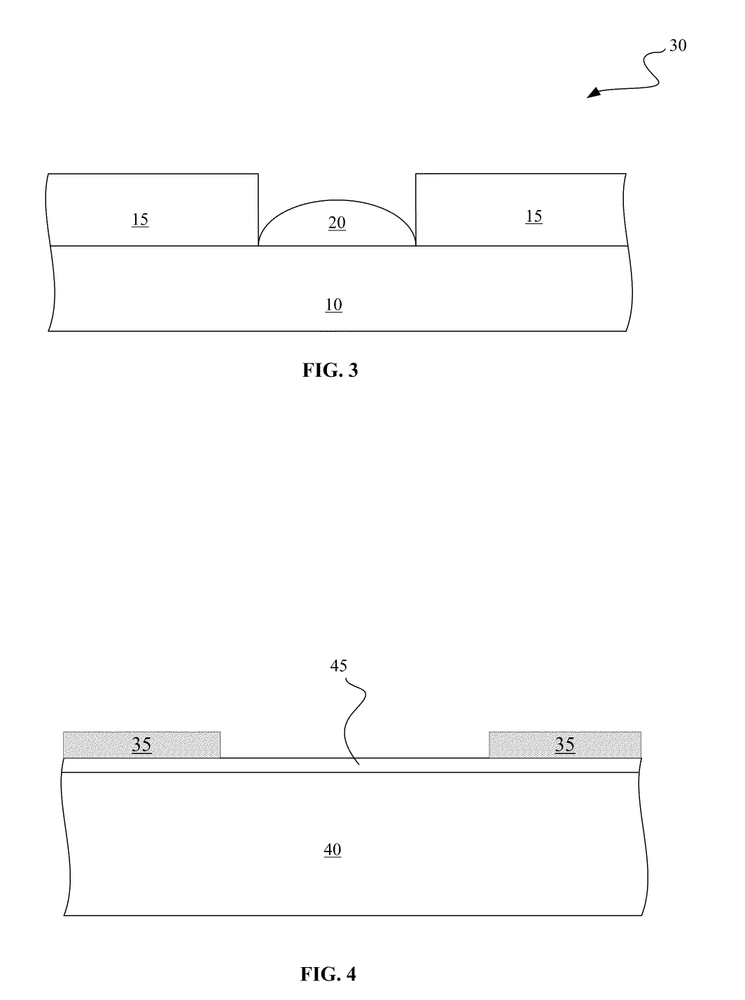

The structure can then have portions of the structure oxidized, effectively removing the nitride layer 15 in those areas without the need of any etching process. In these aspects, a mask 25 is provided on the ONO structure 5 using any process known in the art, as shown in FIG. 2. The mask 25 comprises any non-oxidizing material. A nitride consumption method described is then performed with this mask 25 so that the nitride areas under the mask 25 are protected and the areas not underyling the mask are converted to an oxide layer 20, while preserving the nitride layer 15 under the mask 25. The resulting structure, a localized ONO structure 30, is depicted in FIG. 3 where a ONO structure is present.

This nitride consumption method can be performed with any process that replaces the silicon nitride with silicon oxide and incorporates some nitrogen in the film and liberates some nitrogen in a gaseous form. In some instances, the nitride consumption method can be performed by oxidizing the nitride layer using a hydrogen/oxygen atmosphere. The hydrogen/oxygen atmosphere contains a mixture of free radicals of hydrogen and oxygen so that the resulting film has behavioral characters of an oxide film. The nitride consumption method is performed for a time sufficient to form the oxide layer to the desired depth.

Other conventional methods make localized ONO films by one of two methods. The first method comprises LOCOS-type processing that is used to grow a self limiting (i.e., thin) oxide over the nitride to form the ONO. The second method comprises forming an ONO film, patterning the top oxide layer, and then etching the top oxide and the nitride to leave the bottom oxide. But using these two methods allows the formation of a thick top oxide on the ONO stack with a seamless (i.e., no nitride etch undercut) transition into the oxide region.

Other embodiments of the semiconductor devices and methods for making such devices are shown in FIGS. 4-8. In these embodiments, the consumption of a nitride layer to form an oxide layer is used in a local oxidation of silicon (LOCOS) process. In these embodiments, a silicon substrate 40 is provided. The silicon substrate 40 can optionally contain a silicon epitaxial layer that has been formed on an upper surface thereof. The silicon substrate 40 can optionally contain a dopant (whether p-type or n-type) or plurality of dopants at any concentration known in the art.

The LOCOS process then provides an oxide layer 45 (often called a pad oxide layer) on the upper surface of the Si substrate 40. The oxide layer 45 can be any oxide layer known in the art, including a chemical vapor deposition (CVD) oxide or an oxide layer that is formed by oxidizing the Si substrate 40. The oxide layer 45 can have any thickness for the desired semiconductor device in which it will be used.

The LOCOS process continues when a nitride mask 35 is formed on a portion of the oxide layer 45. The nitride mask 35 can be provided in those areas where further oxidation is not desired. The nitride mask 35 can be made of any nitrogen-containing material that will not be oxidized, such as SiN. The nitride mask 35 can be made using any process known in the art, including a deposition and patterning process. The nitride mask 35 can have any thickness consistent with its operation as an oxidation mask.

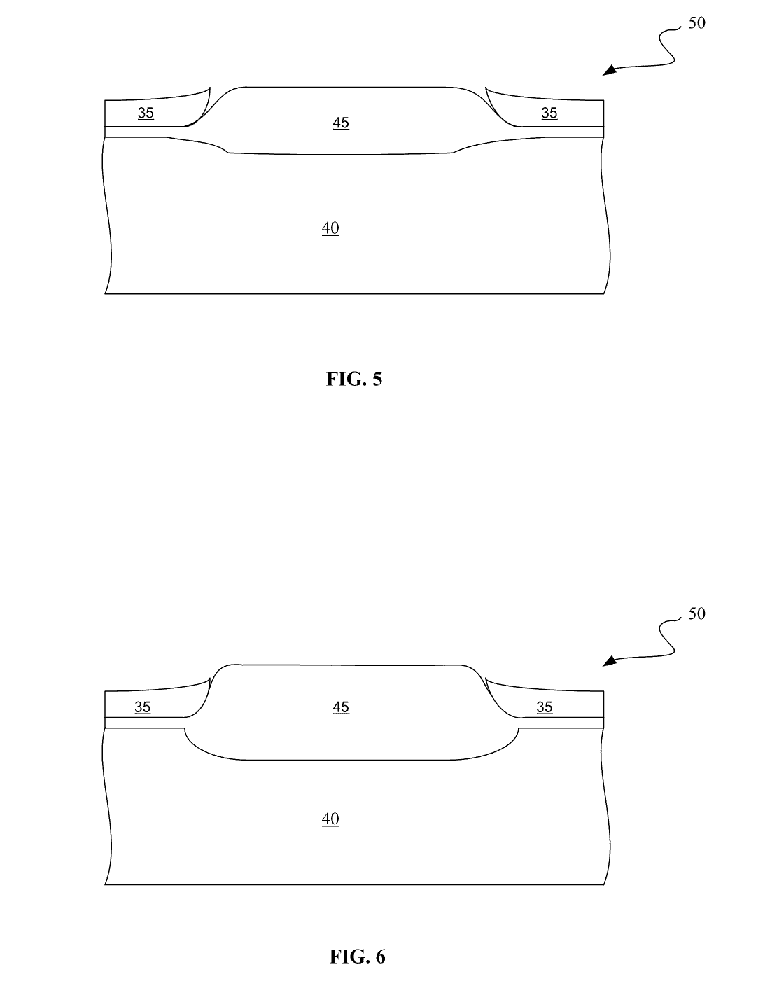

Next, an oxidation process is performed on the resulting structure. During this oxidation process, the thickness of the oxide layer 45 that is not protected by the nitride mask 35 increases to form, for example, a field oxide layer as shown in FIG. 5. In some instances, this oxidation process is performed by heating the structure depicted in FIG. 4 in an oxidizing atmosphere at any temperature until the desired thickness is obtained, as shown in FIG. 6. At this point in conventional processing, the nitride mask 35 is removed by any known etching process.

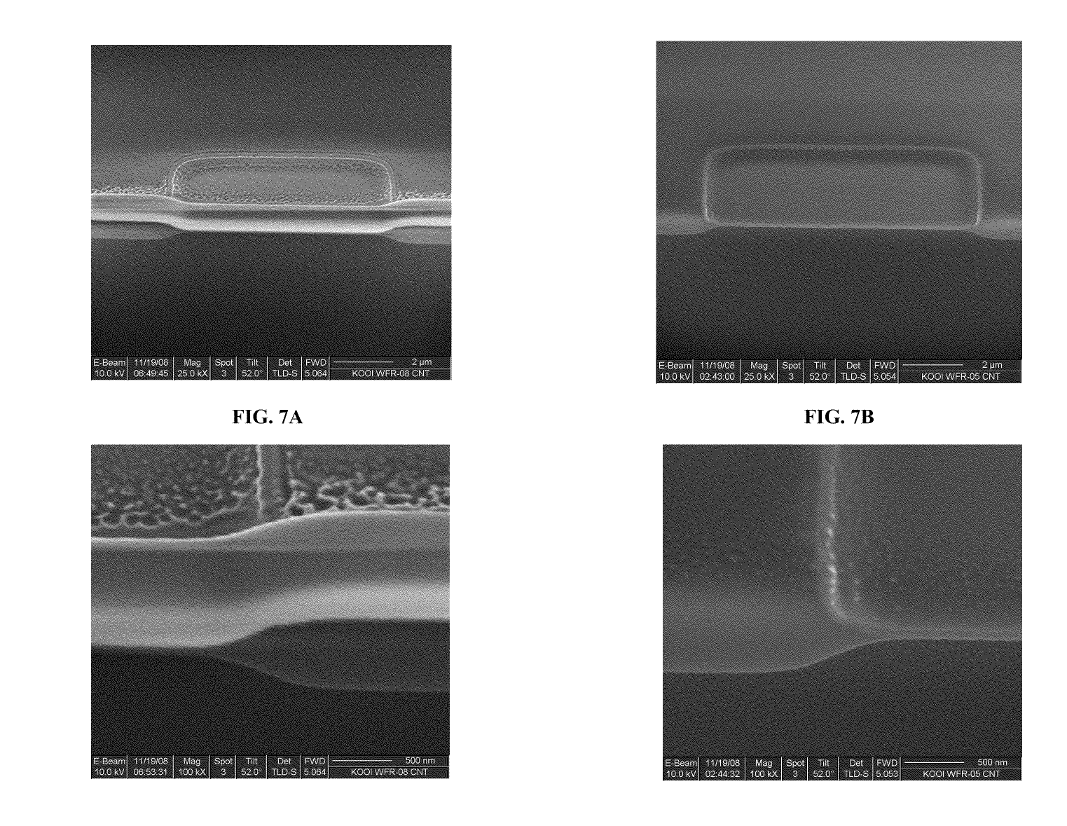

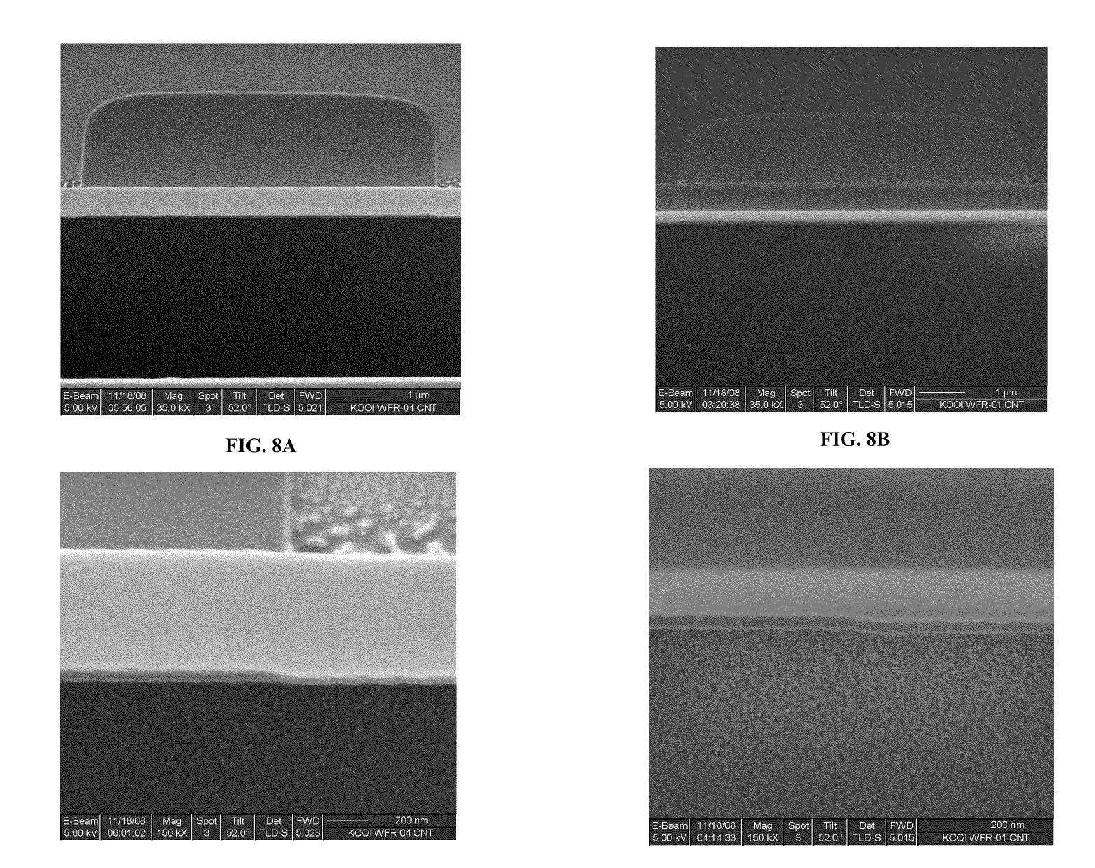

But in some embodiments described herein, a nitride consumption method can be performed on the LOCOS structure 50. The nitride consumption method converts the nitride mask 35 to an oxide layer. Thus, no etching is needed to remove the nitride mask. When such etching is conventionally used to remove the nitride mask, deformations and/or depressions are often left on the upper surface and result in defects during subsequent processing. For example, etching the nitride masks in conventional processing can sometimes result in defects such as the Kooi Ribbon Effect. But by converting the nitride masks into an oxide layer instead of etching them, these defects (including the Kooi Ribbon Effect) can be reduced or eliminated when comparing the structure shown in FIG. 7A (conventional process) with the structure shown in FIG. 7B (nitride consumption process) for a 3000 angstrom oxidation process and the structure shown in FIG. 8A (conventional process) with the structure shown in FIG. 8B (nitride consumption process) for a 500 angstrom oxidation process.

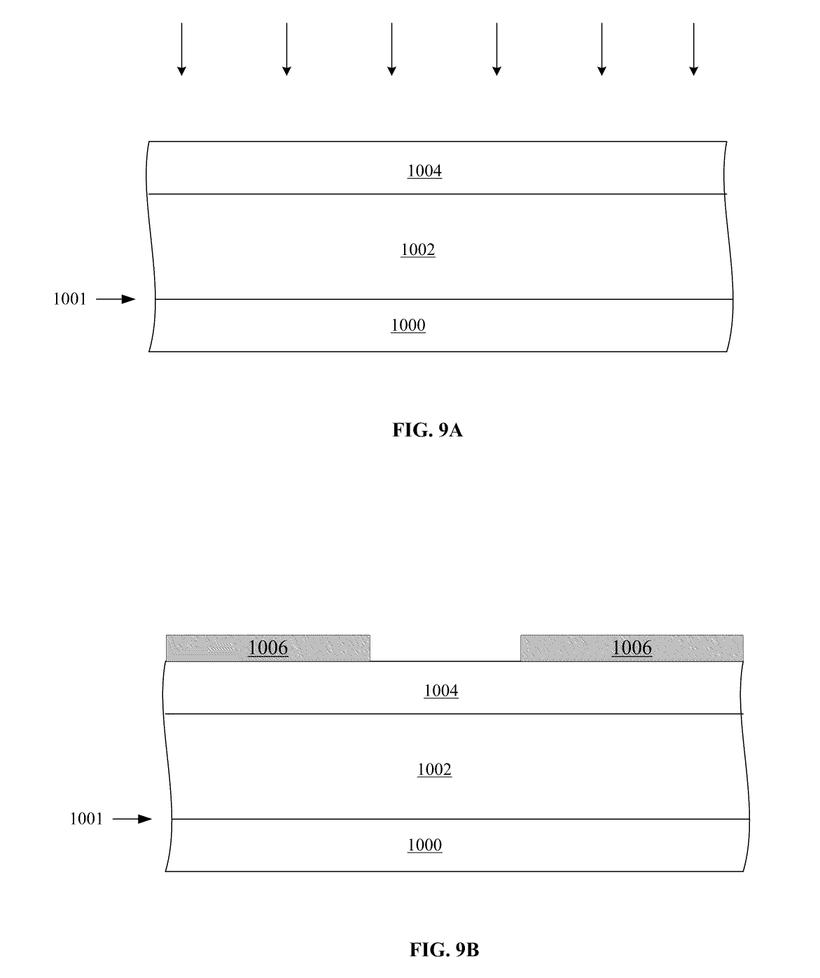

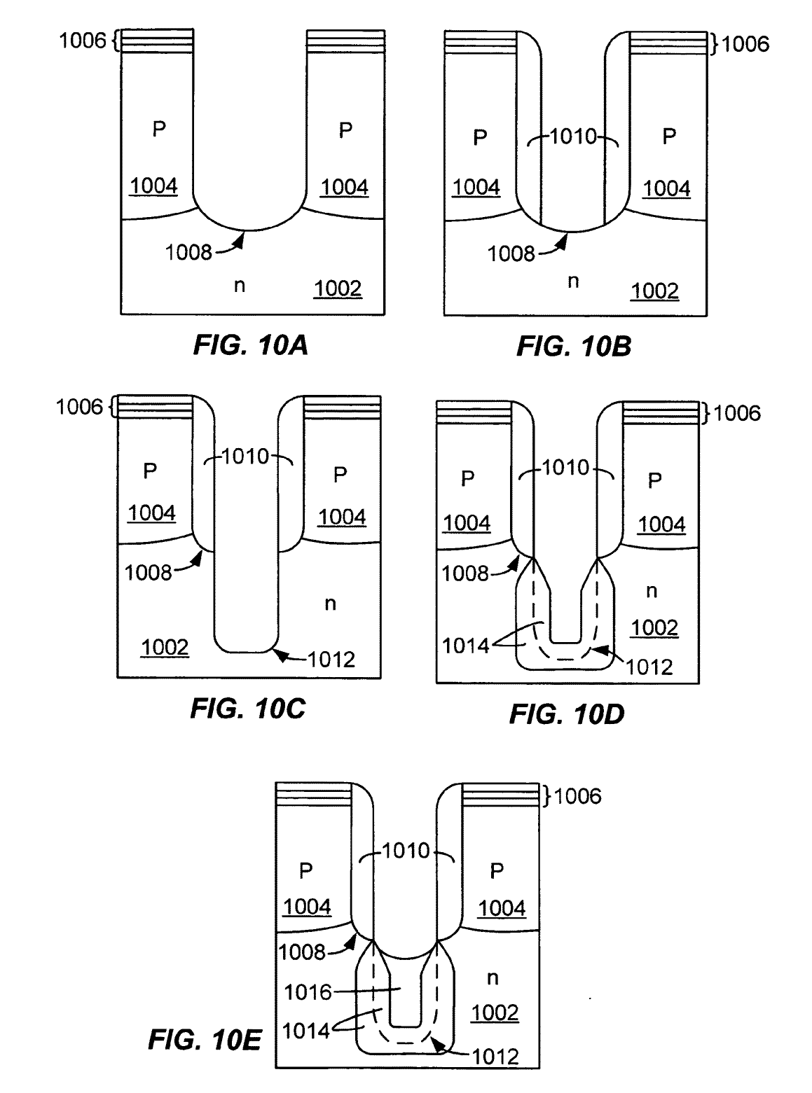

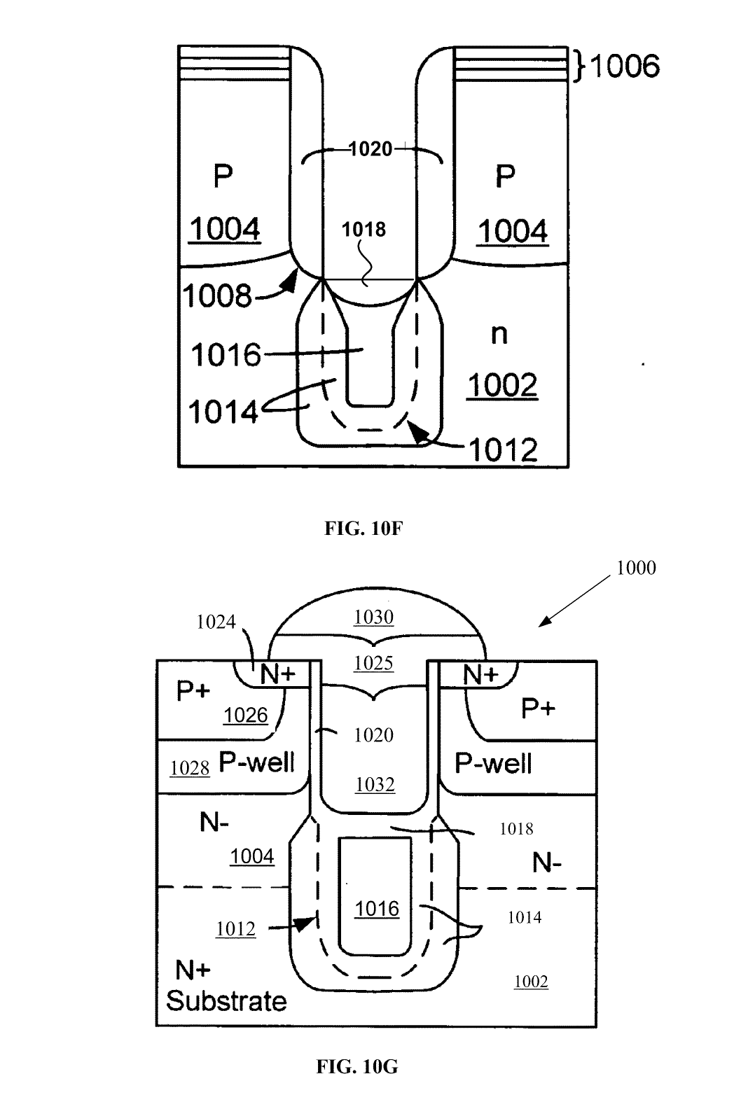

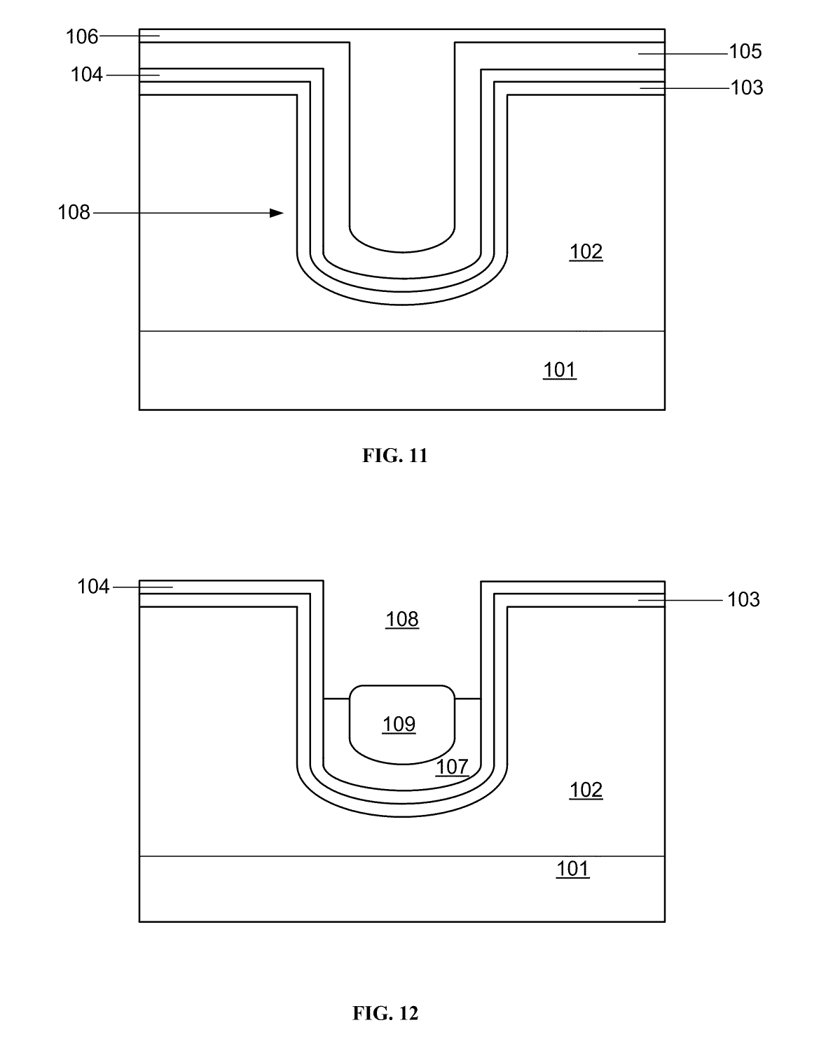

Other embodiments of the semiconductor devices and methods for making such devices are shown in FIGS. 9-10. In these embodiments, the consumption of a nitride layer to form an oxide layer is used in the process for fabricating a trench MOSFET device. The process for making the trench MOSFET begins with a substrate 1001 as shown in FIG. 9A. Any substrate known in the art can be used in the invention. Suitable substrates include silicon wafers, epitaxial Si layers, bonded wafers such as used in silicon-on-insulator (SOI) technologies, and/or amorphous silicon layers, all of which may be doped or undoped.

In some instances, the substrate 1001 contains a single crystal silicon wafer 1000 having at least one epitaxial (“epi”) Si layer 1002 located in an upper region thereof. If desired, more than one epitaxial layer can be provided on the upper surface. The epitaxial layer(s) can be provided using any known process in the art, including any known epitaxial deposition process. The epitaxial layer 1002 can be doped with an n-type dopant to the desired concentration. Next, dopants of p-type conductivity are implanted to form a body region 1004 in an upper portion of the epitaxial layer 1002, as shown in FIG. 9A. A hard mask 1006, e.g., comprising oxide-nitride-oxide (ONO) composite layer can then be formed over the body region 1004 using any known process, as shown in FIG. 9B. The hard mask 1006 can be used to define and etch trenches 1008 extending through body region 1004 and into epitaxial layer 1002, as shown in FIG. 10A, by using any isotropic silicon etching process known in the art.

Next, as shown in FIG. 10B, a dielectric spacer 1010 can be formed to line the trench sidewalls. The dielectric spacer 1010 can be made of any known dielectric material, including silicon nitride. The dielectric spacer 1010 can be formed by any processing known in the art. In some embodiments, the dielectric spacer 1010 is formed from a first oxide layer that is covered by silicon nitride layer so that the surface of the silicon nitride layer is exposed.

Then, as shown in FIG. 10C, an etching process is used to extend the depth of the trench 1008. The dielectric spacer 1010 can be used as a self-alignment mechanism during the etching process. Thus, the trenches 1008 contain a wider upper portion and a narrower lower portion 1012. This etching process can be carried out using any known isotropic silicon etching process.

Next, as shown in FIG. 10D, a LOCOS process is carried out to form a self-aligned shield dielectric layer 1014. The shield dielectric is formed along the exposed silicon surfaces in the trench 1008 in the lower potion 1012. The LOCOS process converts those parts of the silicon in the lower trench portion 1012 into silicon oxide, thereby forming the shield dielectric. The dashed line in FIG. 10D shows the contours of the lower trench portion 1012. The LOCOS process can be performed by any known process in the art.

Then, as shown in FIG. 10E, a shield electrode 1016 is formed by any process known in the art. In some embodiments, the shield electronic 1016 is formed by depositing a layer of polysilicon (or other conductive material) to fill the trench 1008 and then etching back so that the polysilicon layer is recessed in the trench 1008.

Next, an interpoly dielectric (IPD) layer 1018 is formed, as shown in FIG. 10F. The IPD layer 1018 can be formed by carrying out any known thermal oxidation of the structure shown in FIG. 10E. A layer of silicon oxide forms only over shield electrode 1016 since all other silicon surfaces are covered either by nitride or by oxide. The thickness of the IPD layer 1018 can therefore be adjusted to any thickness needed for the MOSFET device that will be formed in the trench. Then, an etching process etch is carried out to remove the hard mask 1006.

Next, a nitride consumption process substantially similar to that described herein can be carried out on the exposed nitride surfaces of the dielectric spacer 1010. The nitride consumption process results in a high quality oxide layer 1020 being formed on the sidewalls of the upper portion of the trench. This high quality oxide layer will serve as the gate oxide 1020 in the channel of the trench MOSFET device.

The process continues when a layer of polysilicon (or other conductive material) is deposited which fills the remainder of the upper portion of the trench 1008. The polysilicon layer can be deposited using any process known in the art. This polysilicon layer is then etched back to form a recessed gate electrode 1032 in the trench. This etching process can be performed using any process known in the art.

Next, n-type dopant regions 1024, p+ regions 1026, and p-wells 1028 are formed as known in the art. Then, a doped dielectric layer 1025 (i.e., BPSG) is formed over the trench 1008 and the mesa using any known methods. A reflow process is carried out to obtain a better step coverage for a source interconnect layer 1030 that is formed over the BPSG layer 1025 as known in the art.

FIG. 10G shows a cross section view of a dual gate trench MOSFET 1000 wherein the shield dielectric 1014 is formed using LOCOS process. The dashed line 1012 shows the contours of the trench 1008. In forming the shield dielectric layer 1014, the LOCOS process results in consumption of the silicon adjacent trench 1008 thus causing the shield dielectric to flare out and extend directly under body regions 1004. The LOCOS process is a cost effective method of forming the shield dielectric layer, and also yields a uniform film. The IPD layer 1018 can be formed entirely from a thermally grown oxide and therefore can be adjusted to any thickness needed with minimal effect of the gate oxide. As well, the dual gate trench MOSFET 1000 contains an IPD oxide layer 1018 and gate oxide layer 1020 that are formed without using a nitride etch.

Conventional shielded gate IPD layers are either created by growing a thermal oxide at a faster rate than the channel gate layer or by using a CVD oxide to increase the thickness of the IPD layer. But these conventional methods restrict the amount of IPD oxide that can be thermally grown because the channel gate is not shielded from the oxidation. But using the processes described herein, the gate channel nitride acts as a barrier to the oxidation so the IPD oxide can be grown to any needed thickness with minimal oxidation to the channel gate. As well, unlike conventional methods, the gate poly-Si finger is eliminated reducing the electric field (leakage) at the channel to IPD interface.

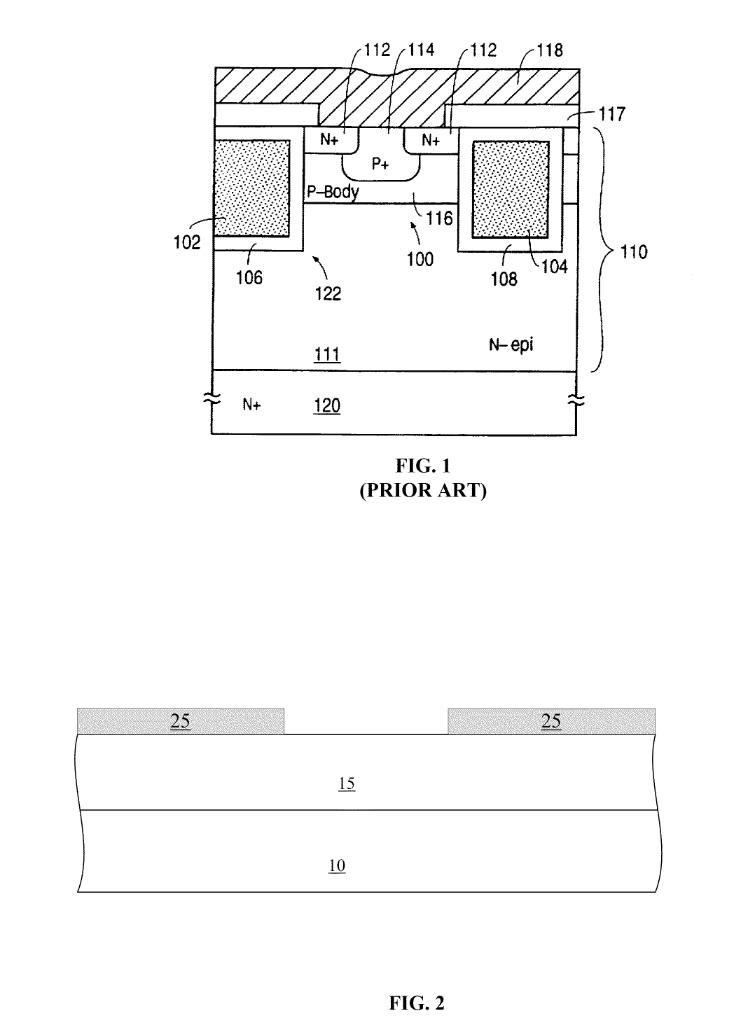

The formation of an oxygen layer by consumption of a nitride layer can be modified to form other types of trench MOSFET structures. For example, while trench 1008 and the shield electrode 1016 are shown extending into substrate 1002, they may alternatively terminate in an n− region. As well, the nitride consumption methods described herein could be use to form a single gate trench MOSFET device, such as that depicted in FIG. 1.

Other embodiments of the semiconductor devices and methods for making such devices are shown in FIGS. 11-15. In these embodiments, which are formed similar to those described above, the consumption of a nitride layer to form an oxide layer is used in the process for fabricating a shielded-gate trench MOSFET device. In these embodiments, the process for making the trench MOSFET begins with providing a substrate 101 as shown in FIG. 11. Substrate 101 can be substantially similar to substrate 1001. If desired, an epitaxial layer 102 similar to epitaxial layer 1002 can optionally be provided. Optionally, a body region (substantially similar to body region 1004) can be formed in an upper portion of the epitaxial layer 102. Then, a mask can used to make a trench 108 (substantially similar to trench 1008) after which the mask is removed to leave the trench 108 formed in the substrate 101.

Next, as shown in FIG. 11, an oxide layer 103 is formed on upper surface of the substrate and in the trench. In some embodiments, the oxide layer 103 comprises a pad oxide layer. The oxide layer 103 can be any oxide layer known in the art, including a chemical vapor deposition (CVD) oxide or an oxide layer that is formed by oxidizing the Si substrate 101 containing the trench. The oxide layer 103 can have any thickness for the desired semiconductor device in which it will be used.

Next, as shown in FIG. 11, a nitride layer 104 can be formed on the pad oxide layer 103 using any process known in the art. In some embodiments, the nitride layer 104 can be a CVD nitride layer or a nitride layer that is formed by nitriding the underlying oxide layer 103 using any process known in the art. The nitride layer 104 can have any thickness that is needed for blocking oxidation, including a thickness ranging from about 100 to about 1000 A.

Next, as shown in FIG. 11, an oxide layer 105 is formed over the nitride layer 104. The oxide layer 105 can be any oxide layer known in the art, including a chemical vapor deposition (CVD) oxide or other oxide layer that can be deposited on the nitride layer. The oxide layer 105 will be used to form a shield oxide in the trench MOSFET structure. Accordingly, the oxide layer 105 can have any thickness for that will serve as a shield oxide layer.

Next, as shown in FIG. 11, a conductive layer 106 is deposited on the upper surface and the trench. The conductive layer 106 will be used to form a shield electrode. Thus, any conductive material known in the art can be used in conductive layer 106, including polysilicon. The conductive layer 106 can be formed using any known process for the selected conductive material. The conductive layer can have any thickness that can be used to form a shield electrode.

Then, as shown in FIG. 12, a shield oxide layer 107 and a shield electrode 109 can be formed by any process known in the art. In some embodiments, the shield oxide layer 107 and a shield electrode 109 can be formed by etching the oxide layer 105 and the conductive layer 109 until the desired depth is reached in the trench 108. As shown in FIG. 12, the height of the shield electrode is greater than the height of the shield oxide 107.

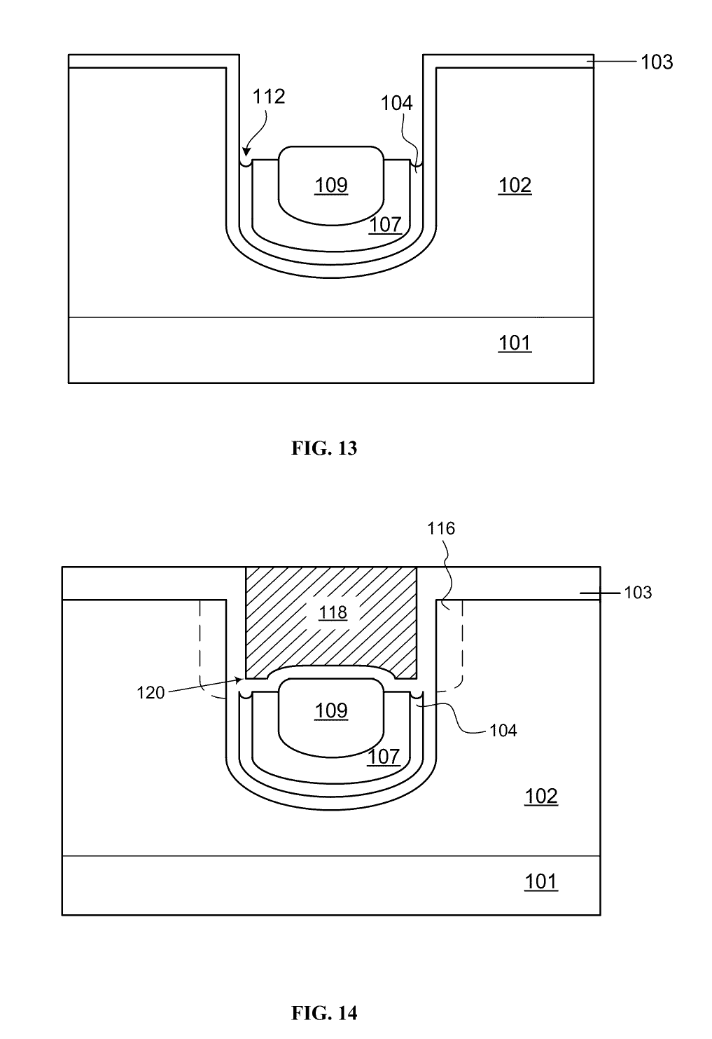

At this stage in conventional processing, the nitride layer 104 is removed. When etching processes are used to remove the nitride layer, a part of the nitride layer between the pad oxide layer and the shield oxide layer is removed because of that etching process. The resulting structure, as illustrated in FIG. 13, contains a lip 112 in an upper surface of the remaining nitride layer 104 between the shield oxide and the pad oxide.

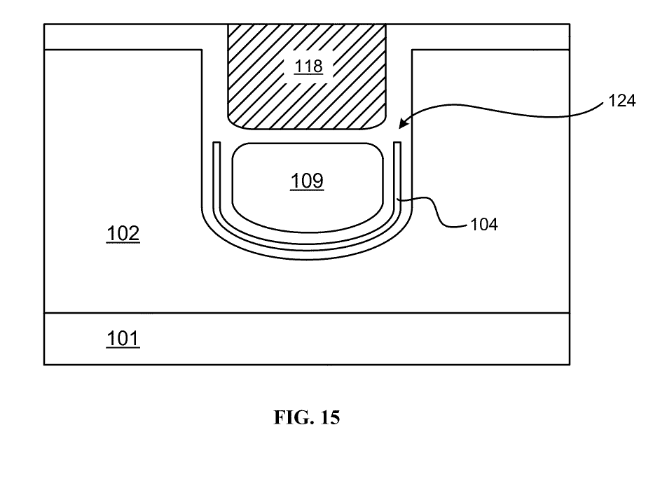

When another oxide layer (which serves as the IPD layer) is then thermally grown on structure of FIG. 13, several problems arise. First, when the upper gate is formed in the upper portion of the trench, the lower portion of the gate contains extending fingers 120 as shown in FIG. 14. These fingers can cause electric field leakage at the channel to the IPD layer interface. A second problem resulting from this thermal oxidation is that the process consumes part of the silicon in the substrate 101. In the thermal oxidation process, some of the Si is converted to a silicon oxide 116 as illustrates in FIG. 14. The result of this Si conversion is that the width of the upper portion of the trench (where upper gate 118 is located) is increased relative to the lower portion of the trench (where gate 109 is located). Such a configuration detracts from the efficient operation of the trench MOSFET. So these conventional methods restrict the amount of the IPD oxide that can be thermally grown because the channel gate is not shielded from the oxidation.

Accordingly, an etching process is not used in these embodiments to remove the nitride layer 104. Instead, the exposed nitride layer in the upper portion of the trench is converted by the nitrogen consumption methods described herein. During this process, the nitride layer in the upper portion of the trench is converted to an oxide layer without consuming any of the Si in the substrate 101. As well, since the exposed portion of the nitride layer 104 is converted to any oxide layer without forming any lip 112, the gate 118 does not contain any fingers 120, as shown in FIG. 15.

The nitride consumption process forms an IPD layer 124 as shown in FIG. 15. At the same time, this process also converts an upper part of the polysilicon gate 109 into a silicon oxide because of the oxygen in the atmosphere used in the nitrogen consumption process. But this conversion of the polysilicon gate can be controlled to a minimum amount. Thus, the thickness of the IPD layer 124 can be adjusted to any desired thickness needed for the MOSFET device that will be formed in the trench. The nitride consumption process also results in a high quality oxide IPD layer.

The process for forming the MOSFET trench structure continues when a layer of polysilicon (or other conductive material) is deposited which fills the reminder of trench 108. The polysilicon layer can be deposited using any process known in the art. This polysilicon layer is then etched back to form a recessed gate electrode 118 in the trench. This etching process can be performed using any process known in the art. The remainder of the device can then be manufactured as described herein, or as known in the art.

It is understood that all material types provided herein are for illustrative purposes only. Accordingly, one or more of the various dielectric layers in the embodiments described herein may comprise low-k or high-k dielectric materials. For example, one or more of the dielectric layers formed before the first polysilicon deposition may comprise high-k dielectric material, while one or more of the dielectric layers formed after the last polysilicon deposition may comprise low-k dielectric material.

In some configurations, not all of the nitride layer need be converted to oxygen in the various embodiments described above. In these configurations, only an upper part of the nitride is converted to oxide. These configurations can be useful when the resulting oxide layer needs to be less than the combined thickness of the pad oxide layer and the converted nitride thickness for voltage threshold and capacitance reasons. For example, where the required oxide thickness to achieve the required dielectric performance is 250 Å, and the pad oxide is 100 Å and the converted nitride is 200 Å, then the resulting thickness would be 300 Å (a thickness which is 50 Å too much). Yet the dielectric constant for nitride is about half that of oxide. So if you leave 100 Å of the nitride layer unconverted, a dielectric equivalent thickness of 250 Å can be obtained. Another reason to leave the part of the nitride layer is that the nitride can operate as a good barrier film for moisture and contaminant/dopant blocking.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A method for making a trench MOSFET device, comprising:
providing a trench in a silicon substrate;
forming a first oxide layer in the trench and on the upper surface of the substrate;
depositing a nitride layer on the oxide layer;
depositing a second oxide layer on the nitride layer;
depositing a polysilicon layer to cover the second oxide layer;
etching the first and second oxide layers and the polysilicon layer to form a shield oxide and a first polysilicon gate;
converting the nitride layer to a third oxide layer; and
forming a second polysilicon gate in the trench above the third oxide layer.

2. The method of claim 1, wherein the nitride layer is converted to the third oxide layer by heating in an atmosphere containing free radicals of hydrogen and oxygen.

3. The method of claim 1, wherein the nitride layer is converted to the third oxide layer without using any etching processes to remove the nitride layer.

4. The method of claim 1, wherein the third oxide layer is formed without converting substantially any silicon in the substrate into an oxide.

5. The method of claim 1, wherein the width of the trench is not substantially increased when the nitride layer is converted to the third oxide layer.

6. The method of claim 5, wherein the width of the upper part of the trench is substantially the same as the width of the lower part of the trench.

7. The method of claim 1, wherein the second polysilicon gate contains substantially no portion intruding into the second oxide layer.

8. A method for making a semiconductor device, comprising:
providing a silicon substrate;
forming a first oxide layer on the upper surface of the substrate;
depositing a nitride mask on the oxide layer;
increasing the thickness of the first oxide layer not covered by the nitride mask; and
converting the nitride layer to a second oxide layer.

9. The method of claim 8, wherein the nitride layer is converted to the second oxide layer by heating in an atmosphere containing free radicals of hydrogen and oxygen.

10. The method of claim 8, wherein the nitride layer is converted to the second oxide layer without using any etching processes to remove the nitride layer.

11. The method of claim 8, wherein the thickness of the first oxide layer is increased by a LOCOS process.

12. A MOSFET device made by the method comprising:
providing a trench in a silicon substrate;
forming a first oxide layer in the trench and on the upper surface of the substrate;
depositing a nitride layer on the oxide layer;
depositing a second oxide layer on the nitride layer;
depositing a polysilicon layer to cover the second oxide layer;
etching the first and second oxide layers and the polysilicon layer to form a shield oxide and a first polysilicon gate;
converting the nitride layer to a third oxide layer; and
forming a second polysilicon gate in the trench above the third oxide layer.

13. The device of claim 12, wherein the nitride layer is converted to the third oxide layer by heating in an atmosphere containing free radicals of hydrogen and oxygen.

14. The device of claim 12, wherein the nitride layer is converted to the third oxide layer without using any etching processes to remove the nitride layer.

15. The device of claim 12, wherein the third oxide layer is formed without converting substantially any silicon in the substrate into an oxide.

16. The device of claim 12, wherein the width of the trench is not substantially increased when the nitride layer is converted to the third oxide layer.

17. The device of claim 16, wherein the width of the upper part of the trench is substantially the same as the width of the lower part of the trench.

18. The device of claim 12, wherein the second polysilicon gate contains substantially no portion intruding into the second oxide layer.

19. A semiconductor device made by the method, comprising:
providing a silicon substrate;
forming a first oxide layer on the upper surface of the substrate;
depositing a nitride mask on the oxide layer;
increasing the thickness of the first oxide layer not covered by the nitride mask; and
converting the nitride layer to a second oxide layer.

20. The device of claim 19, wherein the nitride layer is converted to the second oxide layer by heating in an atmosphere containing free radicals of hydrogen and oxygen.

21. The device of claim 19, wherein the nitride layer is converted to the second oxide layer without using any etching processes to remove the nitride layer.

22. The device of claim 19, wherein the thickness of the first oxide layer is increased by a LOCOS process.

23. A semiconductor device, comprising:
a silicon substrate containing a trench in an upper portion thereof;
a pad oxide layer located in a bottom portion of the trench;
a nitride layer located on the pad oxide layer;
a shield oxide layer located on the nitride layer;
a first polysilicon gate located on shield oxide layer;
an interpoly dielectric layer located over the first polysilicon gate; and
a second polysilicon gate located on the interpoly dielectric layer in an upper portion of the trench, the second polysilicon gate insulated from the substrate by a nitride layer that has been converted to an oxide layer.

24. The device of claim 23, wherein the upper portion of the trench and the lower portion of the trench have substantially the same width.

25. The device of claim 23, wherein the second polysilicon gate contains substantially no portion intruding into the shield oxide layer.
